(19) United States
(12) Patent Application Publication
(10) Pub. No.: US 2026/0096181 A1
(43) Pub. Date: Apr. 2, 2026

(54) CONFORMAL APPROACHES FOR FABRICATING CONTACTS AND THE RESULTING STRUCTURES

(71) Applicant: Intel Corporation, Santa Clara, CA (US)

(72) Inventors: Ming-Yi SHEN, Portland, OR (US); Shaun MILLS, Hillsboro, OR (US); Jean-Philippe TURMAUD, Portland, OR (US); Tyler NAIBERT, Hillsboro, OR (US); Karan Sandeep KADAKIA, Beaverton, OR (US); Alex HOJEM, Portland, OR (US); Justin E. MUELLER, Portland, OR (US); Chi-Hing CHOI, Portland, OR (US)

(21) Appl. No.: 18/900,007

(22) Filed: Sep. 27, 2024

(51) Int. Cl. H01L 29/45; H01L 29/06; H01L 29/423; H01L 29/775; H01L 29/78; H01L 29/786

(52) U.S. Cl. CPC H10D 64/62; H10D 30/43; H10D 30/6211; H10D 30/6735; H10D 30/6757; H10D 62/121

(57) ABSTRACT

Conformal approaches for fabricating contacts, and semiconductor structures having conformal metal contacts, are described. In an example, an integrated circuit structure includes a nanowire or fin coupled to or including a source or drain structure. A dielectric layer is above the source or drain structure. An opening is in the dielectric layer and extends into the source or drain structure, the opening having a bottom and sidewalls. A conductive liner is along the bottom and the sidewalls of the opening. The conductive liner has a thickness variation of less than 10% throughout the conductive liner with respect to the bottom and the sidewalls of the opening, respectively. A conductive fill is on the conductive liner and in a remainder of the opening. A ratio of an area of the conductive fill to the conductive liner in a cross-sectional perspective is at most 3:1.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant. In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and compatibility with the existing high-yielding bulk silicon substrate infrastructure. Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

Integrated circuits commonly include electrically conductive microelectronic structures, which are known in the arts as vias, to electrically connect metal lines or other interconnects above the vias to metal lines or other interconnects below the vias. Vias are typically formed by a lithographic process. Representatively, a photoresist layer may be spin coated over a dielectric layer, the photoresist layer may be exposed to patterned actinic radiation through a patterned mask, and then the exposed layer may be developed in order to form an opening in the photoresist layer. Next, an opening for the via may be etched in the dielectric layer by using the opening in the photoresist layer as an etch mask. This opening is referred to as a via opening. Finally, the via opening may be filled with one or more metals or other conductive materials to form the via.

Variability in conventional and state-of-the-art fabrication processes may limit the possibility to further extend them into the, e.g. 10 nm or sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIGS. 1A and 1B illustrate cross-sectional views representing various operations in a method of fabricating a conformal contact for a source or drain region, in accordance with an embodiment of the present disclosure.

FIG. 1C illustrates a cross-sectional view of an integrated circuit structure including conformal source or drain contacts, in accordance with an embodiment of the present disclosure.

FIG. 2A illustrates a cross-sectional view of a semiconductor device having a conductive contact on a source or drain region, in accordance with an embodiment of the present disclosure.

FIG. 2B illustrates a cross-sectional view of another semiconductor device having a conductive on a raised source or drain region, in accordance with an embodiment of the present disclosure.

FIG. 3 illustrates a plan view of a plurality of gate lines over a pair of semiconductor fins, in accordance with an embodiment of the present disclosure.

FIGS. 4A-4B illustrate cross-sectional views, taken along the a-a′ axis of FIG. 3, for various operations in a method of fabricating an integrated circuit structure, in accordance with an embodiment of the present disclosure.

FIG. 5 illustrates a cross-sectional view, taken along the b-b′ axis of FIG. 3, for an integrated circuit structure, in accordance with an embodiment of the present disclosure.

FIG. 6 illustrates a plan view and corresponding cross-sectional view of a metallization layer of an integrated circuit structure, in accordance with an embodiment of the present disclosure.

FIG. 7A illustrates a cross-sectional view of a non-planar semiconductor device, in accordance with an embodiment of the present disclosure.

FIG. 7B illustrates a plan view taken along the a-a′ axis of the semiconductor device of FIG. 7A, in accordance with an embodiment of the present disclosure.

FIG. 8 illustrates a computing device in accordance with one implementation of an embodiment of the disclosure.

FIG. 9 is an interposer implementing one or more embodiments of the disclosure.

### DESCRIPTION OF THE EMBODIMENTS

Conformal approaches for fabricating contacts, and integrated circuit structure including semiconductor structures having conformal metal contacts, are described. In the following description, numerous specific details are set forth, such as specific material and device architecture regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to conformal physical vapor deposition (PVD) metallic liner deposition on sub-30 nm interconnects. One or more embodiments described herein are directed to gate-all-around devices fabricated using a conformal contact process. It is to be appreciated that, unless indicated otherwise, reference to nanowires herein can indicate nanowires or nanoribbons or nanosheets. One or more embodiments described herein are directed to FinFET structures fabricated using a conformal contact process.

To provide context, a physical vapor deposition (PVD) metallic liner can be used to replace a resistive/non-metallic liner, such as TiN or WCN. A thick PVD metallic liner has very low electrical resistance, but the PVD thickness can be limited by a metal overhang, which can cause pinch-off for a subsequent atomic layer deposition (ALD) metal fill.

Embodiments described herein can include a conformal (or mostly conformal) PVD metallic liner deposition. The liner can be formed to provide a conformal PVD liner inside a three-dimensional (3D) feature. The PVD deposition on the field (overhang) may be thicker due to line-of-sight physics, but that portion is ultimately removed.

Detectability of the implementation of embodiments described herein can include E-test to reveal a relatively thicker metallic PVD liner that lowers KLV line and/or via resistance. EM EDS/Atom Probe can be used to detect lack of resistive ALD TiN or WCN in the structure, and/or a conformal PVD metallic liner without impurities, and/or minimal intermixing between silicon oxide/PVD metal.

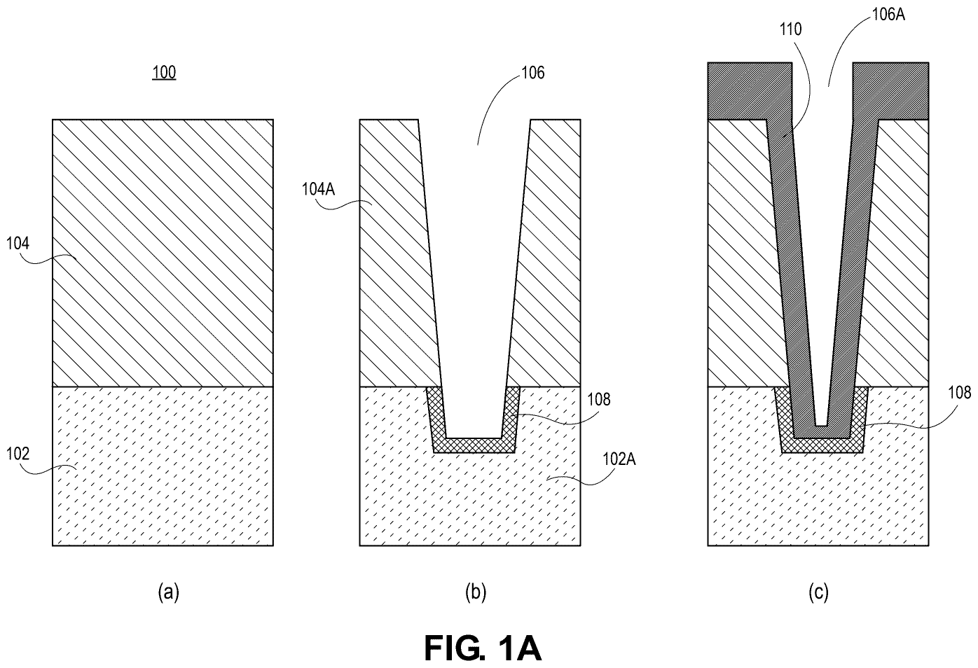

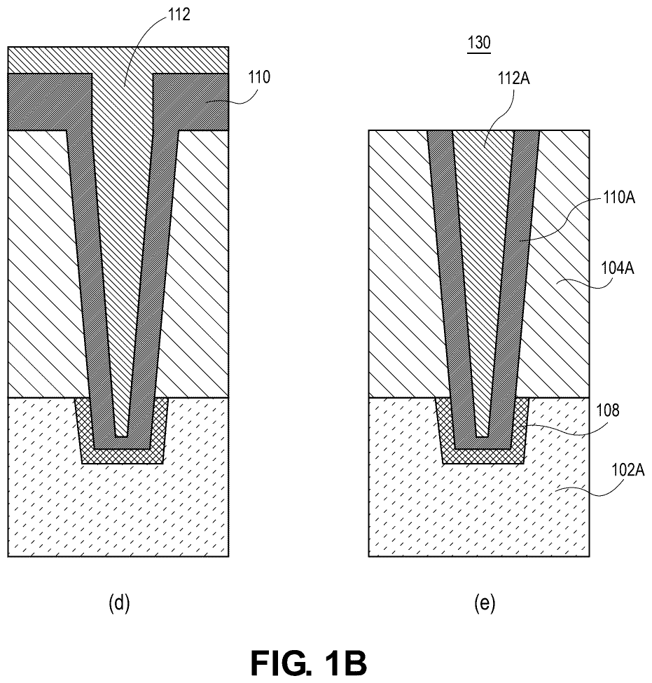

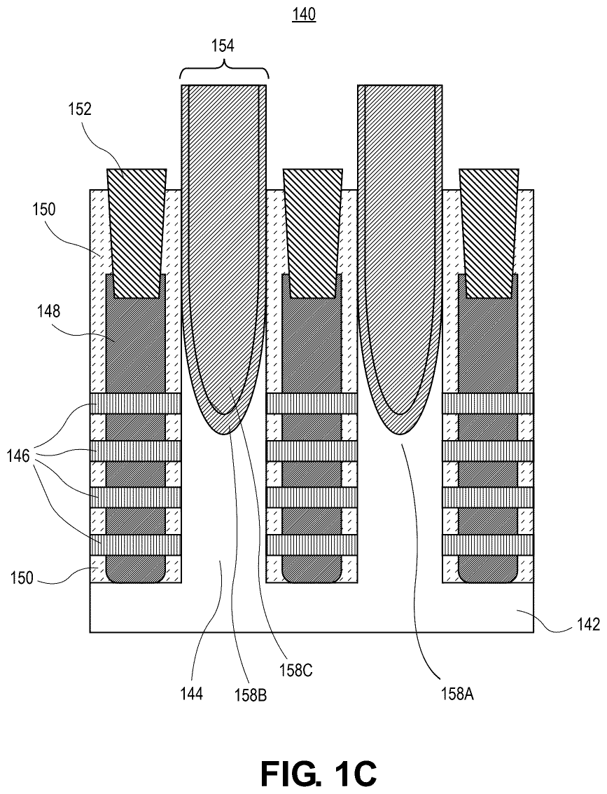

As an exemplary process flow, FIGS. 1A and 1B illustrate cross-sectional views representing various operations in a method of fabricating a conformal contact for a source or drain region, in accordance with an embodiment of the present disclosure.

Referring to part (a) of FIG. 1A, a starting structure 100 includes a dielectric layer 104 on a semiconductor structure 102, such as a source or drain structure. The semiconductor structure 102 can be, e.g., an exposed portion of a bulk substrate or can be an epitaxially grown semiconductor material such as a silicon or silicon germanium source or drain structure. The dielectric layer 104 can be, e.g., a layer such as silicon dioxide or a low-k dielectric material.

Referring to part (b) of FIG. 1A, an opening 106 is formed in the dielectric layer 104 and optionally into the semiconductor structure 102, e.g., by a lithography and etch process, to form a patterned dielectric layer 104A and a patterned semiconductor structure 102A. A metal silicide layer 108, such as a titanium silicide layer, is formed at the exposed portion of the patterned semiconductor structure 102A, e.g., by a metal deposition and removal process that can consume a portion of the patterned semiconductor structure 102A. In one embodiment, the opening 106 is a trench or via having a critical dimension (CD) in the range of 7-30 nanometers.

Referring to part (c) of FIG. 1A, conductive liner 110 is formed in the opening 106 of part (b) of FIG. 1A, leaving remaining a smaller opening 106A. The conductive liner can be formed using a conformal physical vapor deposition (PVD) process, e.g., a process that leaves the same or substantially the same thickness on the bottom and sidewalls of the opening 106. In one embodiment, the conductive liner 110 is or includes a metal or metal alloy such as, but not limited to, Ti, W, Ru, Mo, Cu, Co, CuMn, NiAl, Ta, TiN, or TaN. In one embodiment, the conductive liner 110 has a thickness throughout equal to or greater than 1.5 nanometers with respect to the surface of which the conductive liner 110 is deposited. In one embodiment, the conductive liner 110 has a thickness equal to or greater than 1.5 nanometers and the bottom of the opening 106.

Referring to part (d) of FIG. 1B, a conductive fill 112 is formed in the opening 106A of part (c) of FIG. 1A, e.g., using an atomic layer deposition (ALD), a chemical vapor deposition (CVD) process or a second physical vapor deposition process. In one embodiment, the conductive fill 112 is or includes a metal or metal alloy such as, but not limited to, W, Ru, Mo, Cu, Co, or NiAl.

Referring to part (e) of FIG. 1B, a structure 130 is formed by planarizing the structure of part (d) of FIG. 1B, e.g., by a chemical mechanical polishing (CMP) process, to form planarized conductive liner 110A and planarized conductive fill 112A.

With reference again to part (e) of FIG. 1B, in accordance with an embodiment of the present disclosure, an integrated circuit structure 130 includes a dielectric layer 104A above a source or drain structure 102A. An opening 106 is in the dielectric layer 104A and extends into the source or drain structure 102A, the opening having a bottom and sidewalls. A conductive contact can be formed in the opening. For example, a conductive contact includes a conductive liner 110A along the bottom and the sidewalls of the opening. A conductive fill 112A is on the conductive liner and fills a remainder 106A of the opening 106.

In an embodiment, the conductive liner 110A has a thickness variation of less than 10%, or less than 5%, or less than 1%, throughout the conductive liner 110A with respect to the bottom and the sidewalls of the opening 106, respectively. In an embodiment, a small thickness variation can be referred to as a uniform thickness. In an embodiment, a ratio of an area of the conductive fill to the conductive liner in a cross-sectional perspective is at most 3:1, or at most 2:1, or nearly 1:1.

In an embodiment, a metal silicide layer 108, such as a titanium silicide layer, is intervening between the source or drain structure 102A and the conductive liner 110A. In an embodiment, a metal silicide layer 108 including silicon and titanium is intervening between the source or drain structure 102A and the conductive liner 110A.

In an embodiment, the conductive liner 110A includes a metal or metal alloy selected from the group consisting of Ti, W, Ru, Mo, Cu, Co, CuMn, NiAl, Ta, TiN, and TaN. In an embodiment, the conductive fill 112A includes a metal or metal alloy selected from the group consisting of W, Ru, Mo, Cu, Co, and NiAl.

In an embodiment, a nanowire is coupled to or includes the source or drain structure 102A. In an embodiment, a fin is coupled to or includes the source or drain structure 102A. In one embodiment, the nanowire or the fin includes silicon, and the source or drain structure 102A includes silicon or silicon and germanium.

It is to be appreciated that contacts other than source or drain contacts can be a contact such as described above (conformal conductive liner plus conductive fill), such as but not limited to gate contacts, trench contacts (to multiple source or drain structures), via contacts, or deep via bars. It is to be appreciated that structures other than contacts can be formed using the conformal liner plus metal fill approach described above such as but not limited to front side metallization, backside metallization, or gate electrodes. It is to be appreciated that device types (e.g., fin, planar) other than the nanowires described above can incorporate contacts such as those described above).

As an exemplary implementation, FIG. 1C illustrates a cross-sectional view of an integrated circuit structure including conformal source or drain contacts, in accordance with an embodiment of the present disclosure.

Referring to FIG. 1C, an integrated circuit structure 140 includes a substrate 142, such as a silicon substrate or silicon sub-fin structure. Epitaxial source or drain structures 144, such as silicon or silicon germanium epitaxial source or drain structures, are on the substrate 142. A plurality of nanowires or nanoribbons or nanosheets 146, such as silicon nanowires or nanoribbons or nanosheets, are above the substrate 142 and coupled to the epitaxial source or drain structures 144. Gate stacks 148, each of which can include a gate dielectric and gate electrode, are over and surround channel regions of the plurality of nanowires or nanoribbons or nanosheets 146. A gate dielectric spacer 150 is on sides of each gate stack 148. A gate contact 152 is on each of the gate stacks 148. A source or drain contact 154 is on a corresponding one of the epitaxial source or drain structures 144. The source or drain contact 154 includes a conformal conductive liner 158B (such as liner 110A), and a conductive fill 158C (such as conductive fill 112A). A silicide region 158A can also be included.

It is to be appreciated that, in a particular embodiment, a nanowire, fin, or source or drain structure may be composed of silicon. As used throughout, a silicon layer may be used to describe a silicon material composed of a very substantial amount of, if not all, silicon. However, it is to be appreciated that, practically, 100% pure Si may be difficult to form and, hence, could include a tiny percentage of carbon, germanium or tin. Such impurities may be included as an unavoidable impurity or component during deposition of Si or may “contaminate” the Si upon diffusion during post deposition processing. As such, embodiments described herein directed to a silicon layer may include a silicon layer that contains a relatively small amount, e.g., “impurity” level, non-Si atoms or species, such as Ge, C or Sn. It is to be appreciated that a silicon layer as described herein may be undoped or may be doped with dopant atoms such as boron, phosphorous or arsenic.

It is to be appreciated that, in another particular embodiment, a nanowire, fin, or source or drain structure may be may be composed of silicon germanium. As used throughout, a silicon germanium layer may be used to describe a silicon germanium material composed of substantial portions of both silicon and germanium, such as at least 5% of both. In some embodiments, the amount of germanium is greater than the amount of silicon. In particular embodiments, a silicon germanium layer includes approximately 60% germanium and approximately 40% silicon (Si₄₀Ge₆₀). In other embodiments, the amount of silicon is greater than the amount of germanium. In particular embodiments, a silicon germanium layer includes approximately 30% germanium and approximately 70% silicon (Si₇₀Ge₃₀). It is to be appreciated that, practically, 100% pure silicon germanium (referred to generally as SiGe) may be difficult to form and, hence, could include a tiny percentage of carbon or tin. Such impurities may be included as an unavoidable impurity or component during deposition of SiGe or may “contaminate” the SiGe upon diffusion during post deposition processing. As such, embodiments described herein directed to a silicon germanium layer may include a silicon germanium layer that contains a relatively small amount, e.g., “impurity” level, non-Ge and non-Si atoms or species, such as carbon or tin. It is to be appreciated that a silicon germanium layer as described herein may be undoped or may be doped with dopant atoms such as boron, phosphorous or arsenic.

It is also to be appreciated that the embodiments described herein can also include other implementations such as nanowires and/or nanoribbons with various widths, thicknesses and/or materials including but not limited to Si. For example, Ge, SiGe, or group III-V materials may be used as channel materials.

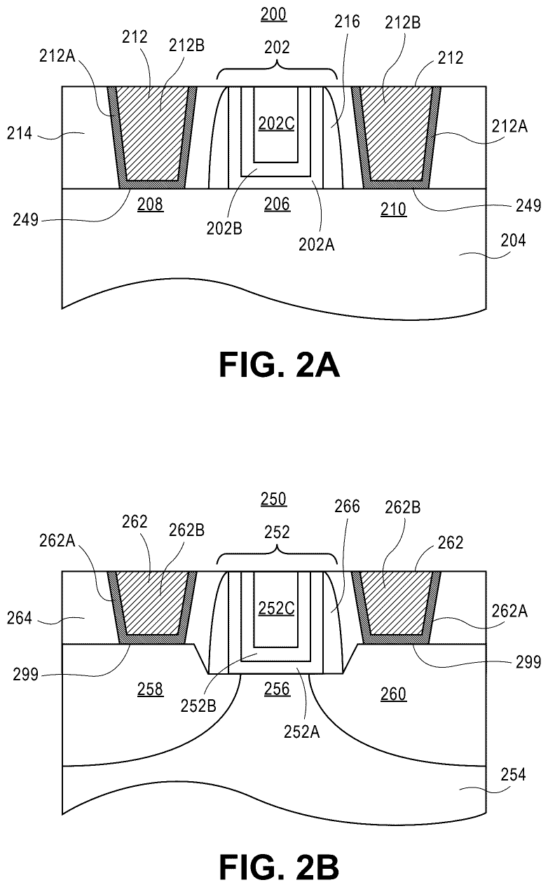

In another, more general, aspect, FIG. 2A illustrates a cross-sectional view of a semiconductor device having a conductive contact on a source or drain region, in accordance with an embodiment of the present disclosure.

Referring to FIG. 2A, a semiconductor structure 200 includes a gate structure 202 above a substrate 204. The gate structure 202 includes a gate dielectric layer 202A, a workfunction layer 202B, and a gate fill 202C. A source region 208 and a drain region 210 are on opposite sides of the gate structure 202. Source or drain contacts 212 are electrically connected to the source region 208 and the drain region 210, and are spaced apart of the gate structure 202 by one or both of an inter-layer dielectric layer 214 or gate dielectric spacers 216. The source region 208 and the drain region 210 are regions of the substrate 204.

In an embodiment, the source or drain contacts 212 each include a conformal conductive liner 212A plus conductive fill 212B, such as described in association with FIGS. 1A-1B.

FIG. 2B illustrates a cross-sectional view of another semiconductor device having a conductive on a raised source or drain region, in accordance with an embodiment of the present disclosure.

Referring to FIG. 2B, a semiconductor structure 250 includes a gate structure 252 above a substrate 254. The gate structure 252 includes a gate dielectric layer 252A, a workfunction layer 252B, and a gate fill 252C. A source region 258 and a drain region 260 are on opposite sides of the gate structure 252. Source or drain contacts 262 are electrically connected to the source region 258 and the drain region 260, and are spaced apart of the gate structure 252 by one or both of an inter-layer dielectric layer 264 or gate dielectric spacers 266. The source region 258 and the drain region 260 are epitaxial and/or embedded material regions formed in etched-out regions of the substrate 254. As is depicted, in an embodiment, the source region 258 and the drain region 260 are raised source and drain regions. In a specific such embodiment, the raised source and drain regions are raised silicon source and drain regions or raised silicon germanium source and drain regions.

In an embodiment, the source or drain contacts 262 each include a conformal conductive liner 262A plus conductive fill 262B, such as described in association with FIGS. 1A-1B.

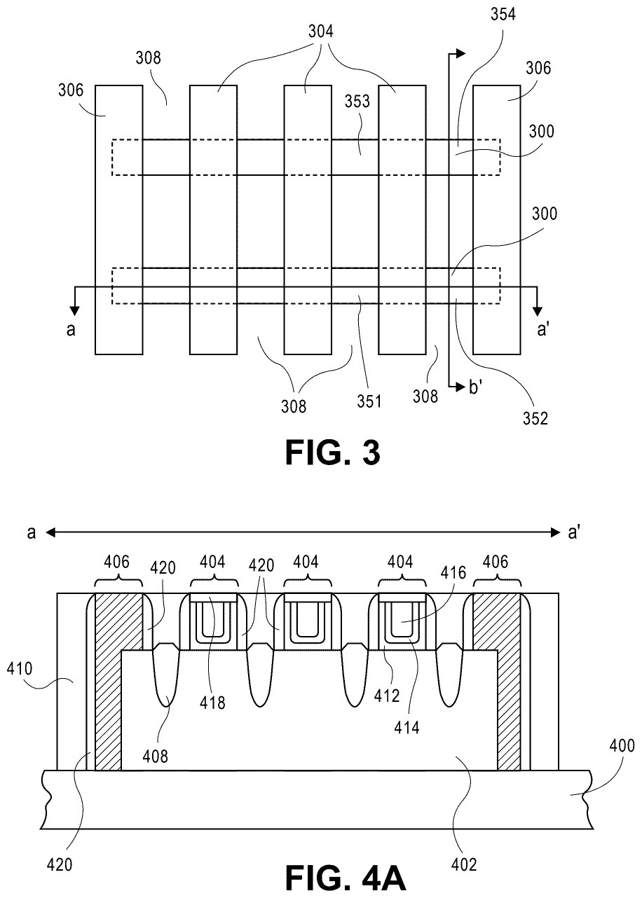

In another aspect, FIG. 3 illustrates a plan view of a plurality of gate lines over a pair of semiconductor fins, in accordance with an embodiment of the present disclosure.

Referring to FIG. 3, a plurality of active gate lines 304 is formed over a plurality of semiconductor fins 300. Dummy gate lines 306 are at the ends of the plurality of semiconductor fins 300. Spacings 308 between the gate lines 304/306 are locations where trench contacts may be formed as conductive contacts to source or drain regions, such as source or drain regions 351, 352, 353, and 354.

In an embodiment, the pattern of the plurality of gate lines 304/306 and/or the pattern of the plurality of semiconductor fins 300 is described as a grating structure. In an embodiment, the term “grating” for the plurality of gate lines 304/306 and/or the pattern of the plurality of semiconductor fins 300 is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have the plurality of gate lines 304/306 and/or the pattern of the plurality of semiconductor fins 300 spaced at a constant pitch and having a constant width. The pattern may be fabricated by a pitch halving or pitch quartering, or other pitch division, approach.

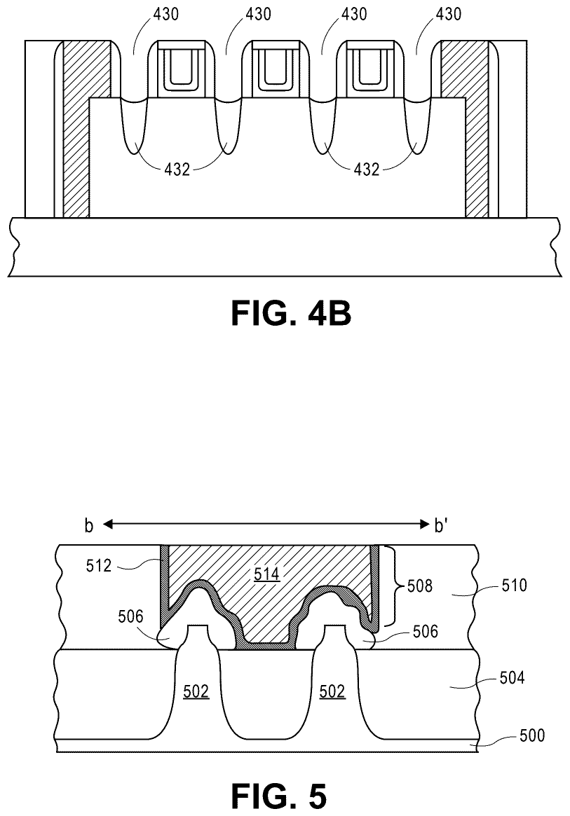

FIGS. 4A-4B illustrate cross-sectional views, taken along the a-a′ axis of FIG. 3, for various operations in a method of fabricating an integrated circuit structure, in accordance with an embodiment of the present disclosure.

Referring to FIG. 4A, a plurality of active gate lines 404 is formed over a semiconductor fin 402 formed above a substrate 400. Dummy gate lines 406 are at the ends of the semiconductor fin 402. A dielectric layer 410 is between the active gate lines 404, between the dummy gate lines 406 and the active gate lines 404, and outside of the dummy gate lines 406. Embedded source or drain structures 408 are in the semiconductor fin 402 between the active gate lines 404 and between the dummy gate lines 406 and the active gate lines 404. The active gate lines 404 include a gate dielectric layer 412, a workfunction gate electrode portion 414 and a fill gate electrode portion 416, and a dielectric capping layer 418. Dielectric spacers 420 line the sidewalls of the active gate lines 404 and the dummy gate lines 406.

Referring to FIG. 4B, the portion of the dielectric layer 410 between the active gate lines 404 and between the dummy gate lines 406 and the active gate lines 404 is removed to provide openings 430 in locations where trench contacts are to be formed. Removal of the portion of the dielectric layer 410 between the active gate lines 404 and between the dummy gate lines 406 and the active gate lines 404 may lead to erosion of the embedded source or drain structures 408 to provide eroded embedded source or drain structures 432 which may have an upper saddle-shaped topography, as is depicted in FIG. 4B.

Referring again to FIG. 4B, trench contacts can be formed in openings 430 between the active gate lines 404 and between the dummy gate lines 406 and the active gate lines 404. Each of the trench contacts may include a conformal conductive liner plus conductive fill, such as described in association with FIGS. 1A-1B.

FIG. 5 illustrates a cross-sectional view, taken along the b-b′ axis of FIG. 3, for an integrated circuit structure, in accordance with an embodiment of the present disclosure.

Referring to FIG. 5, fins 502 are depicted above a substrate 500. Lower portions of the fins 502 are surrounded by a trench isolation material 504. Upper portions of fins 502 have been removed to enable growth of embedded source and drain structures 506. A trench contact 508 is formed in an opening of a dielectric layer 510, the opening exposing the embedded source and drain structures 506. In an embodiment, the trench contact includes a conformal conductive liner 512 plus conductive fill 514, such as described in association with FIGS. 1A-1B.

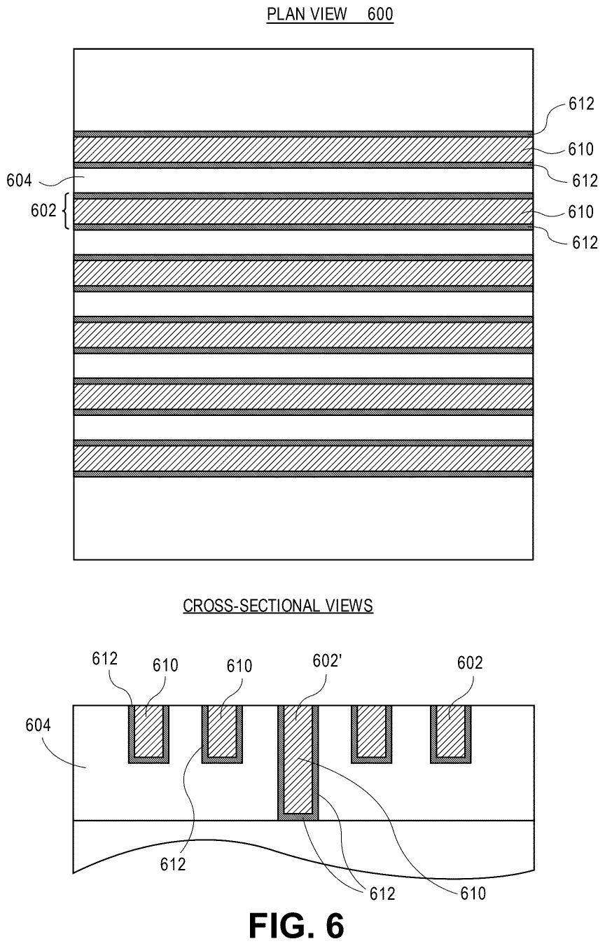

In another aspect, FIG. 6 illustrates a plan view and corresponding cross-sectional view of a metallization layer of an integrated circuit structure, in accordance with an embodiment of the present disclosure.

Referring to FIG. 6, a metallization layer 600 includes a pattern of conductive lines 602 and interlayer dielectric (ILD) lines 604. The metallization layer 600 may be patterned in a grating-like pattern with conductive lines 602 spaced at a constant pitch and having a constant width, as is depicted in FIG. 6. Although not shown, the conductive lines 602 may have interruptions (i.e., cuts or plugs) at various locations along the lines. Some of the conductive lines may be associated with underlying vias, such as line 602′ shown as an example in the cross-sectional view.

In an embodiment, the term “grating” for conductive lines 602 and ILD lines 604 is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have conductive lines 602 and/or ILD lines 604 spaced at a constant pitch and having a constant width. The pattern may be fabricated by a pitch halving or pitch quartering, or other pitch division, approach.

In an embodiment, the conductive lines 602 (and, possibly, underlying via structures) are composed of one or more metal or other conductive structures. The conductive lines 602 are also sometimes referred to in the art as traces, wires, lines, metal, interconnect lines or simply interconnects. In a particular embodiment, each of the conductive lines 602 includes a conformal conductive liner 612 plus conductive fill 610, such as described in association with FIGS. 1A-1B.

In an embodiment, ILD lines 604 are composed of or includes a layer of a dielectric or insulating material. Examples of suitable dielectric materials include, but are not limited to, oxides of silicon (e.g., silicon dioxide (SiO₂)), doped oxides of silicon, fluorinated oxides of silicon, carbon doped oxides of silicon, various low-k dielectric materials known in the arts, and combinations thereof. The interlayer dielectric material may be formed by conventional techniques, such as, for example, chemical vapor deposition (CVD), physical vapor deposition (PVD), or by other deposition methods.

It is to be appreciated that the layers and materials described in association with FIG. 6 are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, although not depicted, the structure depicted in FIG. 6 may be fabricated on underlying lower level back end of line (BEOL) interconnect layers.

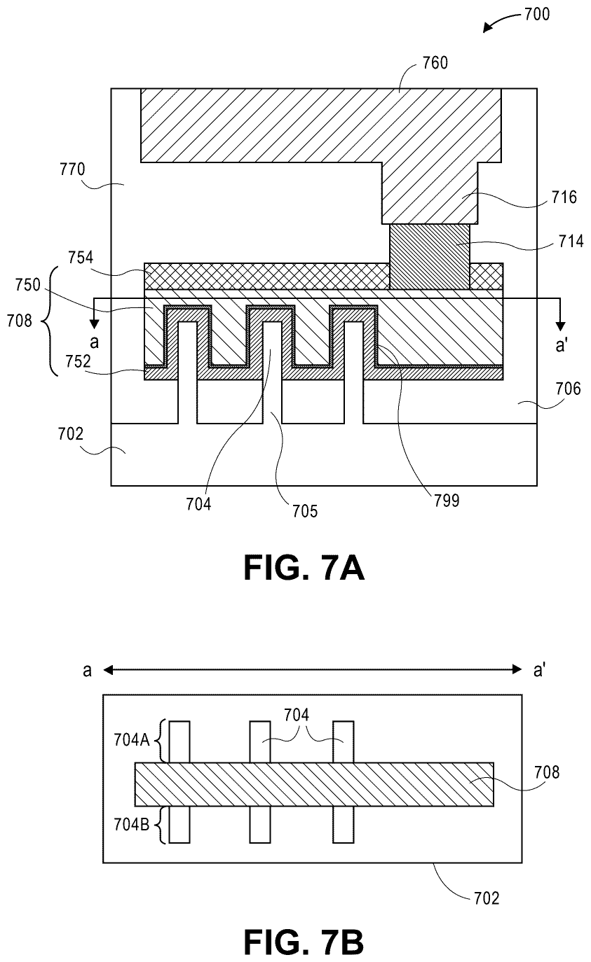

One or more embodiments described herein are directed to fabricating semiconductor devices, such as for metal oxide semiconductor (MOS) device fabrication. As an example, FIG. 7A illustrates a cross-sectional view of a non-planar semiconductor device, in accordance with an embodiment of the present disclosure. FIG. 7B illustrates a plan view taken along the a-a′ axis of the semiconductor device of FIG. 7A, in accordance with an embodiment of the present disclosure.

Referring to FIG. 7A, a semiconductor structure or device 700 includes a non-planar active region (e.g., a fin structure including protruding fin portion 704 and sub-fin region 705) formed from substrate 702, and within isolation region 706. A gate line 708 is disposed over the protruding portions 704 of the non-planar active region as well as over a portion of the isolation region 706. As shown, gate line 708 includes a gate electrode 750/799 and a gate dielectric layer 752. In one embodiment, gate line 708 may also include a dielectric cap layer 754. A gate contact 714, and overlying gate contact via 716 are also seen from this perspective, along with an overlying metal interconnect 760, all of which are disposed in inter-layer dielectric stacks or layers 770. Also seen from the perspective of FIG. 7A, the gate contact 714 is, in one embodiment, disposed over isolation region 706, but not over the non-planar active regions.

In an embodiment, the gate contact includes a conformal conductive liner plus conductive fill, such as described in association with FIGS. 1A-1B.

In accordance with an embodiment of the present disclosure, the layer 799 of gate electrode 750/799 is a P-type workfunction metal or an N-type workfunction metal, depending on whether the transistor is to be a PMOS or an NMOS transistor. In some implementations, the gate electrode layer 750 may consist of a stack of two or more metal layers, where one or more metal layers are workfunction metal layers and at least one metal layer is a conductive fill layer. For a PMOS transistor, metals that may be used for the gate electrode include, but are not limited to, ruthenium, palladium, platinum, cobalt, nickel, tungsten and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

Referring to FIG. 7B, the gate line 708 is shown as disposed over the protruding fin portions 704. Source and drain regions 704A and 704B of the protruding fin portions 704 can be seen from this perspective. In one embodiment, the source and drain regions 704A and 704B are doped portions of original material of the protruding fin portions 704. In another embodiment, the material of the protruding fin portions 704 is removed and replaced with another semiconductor material, e.g., by epitaxial deposition. In either case, the source and drain regions 704A and 704B may extend below the height of dielectric layer 706, i.e., into the sub-fin region 705.

In an embodiment, source and drain regions 704A and 704B have an associated source or drain contact that includes a conformal conductive liner plus conductive fill, such as described in association with FIGS. 1A-1B.

In an embodiment, the semiconductor structure or device 700 is a non-planar device such as, but not limited to, a fin-FET or a tri-gate device. In such an embodiment, a corresponding semiconducting channel region is composed of or is formed in a three-dimensional body. In one such embodiment, the gate electrode and gate electrode materials of gate lines 708 surround at least a top surface and a pair of sidewalls of the three-dimensional body.

Substrate 702 may be composed of a semiconductor material that can withstand a manufacturing process and in which charge can migrate. In an embodiment, substrate 702 is a bulk substrate composed of a crystalline silicon, silicon/germanium or germanium layer doped with a charge carrier, such as but not limited to phosphorus, arsenic, antimony, boron, gallium or a combination thereof, to form active region 704. In one embodiment, the concentration of silicon atoms in bulk substrate 702 is greater than 97%. In another embodiment, bulk substrate 702 is composed of an epitaxial layer grown atop a distinct crystalline substrate, e.g. a silicon epitaxial layer grown atop a boron-doped bulk silicon mono-crystalline substrate. Bulk substrate 702 may alternatively be composed of a group III-V material. In an embodiment, bulk substrate 702 is composed of a III-V material such as, but not limited to, gallium nitride, gallium phosphide, gallium arsenide, indium phosphide, indium antimonide, indium gallium arsenide, aluminum gallium arsenide, indium gallium phosphide, or a combination thereof. In one embodiment, bulk substrate 702 is composed of a III-V material and the charge-carrier dopant impurity atoms are ones such as, but not limited to, magnesium, beryllium, zinc, carbon, silicon, germanium, oxygen, sulfur, selenium or tellurium.

Isolation region 706 may be composed of a material suitable to ultimately electrically isolate, or contribute to the isolation of, portions of a permanent gate structure from an underlying bulk substrate or isolate active regions formed within an underlying bulk substrate, such as isolating fin active regions. For example, in one embodiment, the isolation region 706 is composed of a dielectric material such as, but not limited to, silicon dioxide, silicon oxy-nitride, silicon nitride, or carbon-doped silicon nitride.

In an embodiment, the gate dielectric layer 752 is composed of a high-k material. For example, in one embodiment, the gate dielectric layer 752 is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. Furthermore, a portion of gate dielectric layer may include a layer of native oxide formed from the top few layers of the substrate 702. In an embodiment, the gate dielectric layer is composed of a top high-k portion and a lower portion composed of an oxide of a semiconductor material. In one embodiment, the gate dielectric layer 752 is composed of a top portion of hafnium oxide and a bottom portion of silicon dioxide or silicon oxy-nitride.

In an embodiment, layer 750 of the gate electrode 750/799 is composed of a non-workfunction-setting conductive fill material formed above the workfunction-setting layer 799. In one such embodiment, the conductive fill material 750 includes a material such as but not limited to, tungsten (W), aluminum (Al), or copper (Cu). In one embodiment, one or more conductive barrier layers (such as titanium nitride or tantalum nitride) is between layers 750 and 799 of the gate electrode. In some implementations, the gate electrode may consist of a “U” shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In an embodiment, the dielectric cap layer 754 and/or dielectric spacers associated with the gate electrode stacks may be composed of a material suitable to ultimately electrically isolate, or contribute to the isolation of, a permanent gate structure from adjacent or overlying conductive contacts, such as self-aligned contacts. For example, in one embodiment, the dielectric cap layer 754 and/or dielectric spacers are composed of a dielectric material such as, but not limited to, silicon dioxide, silicon oxy-nitride, silicon nitride, or carbon-doped silicon nitride.

Overlying gate contact via 716 and/or overlying metal interconnect 760 may be composed of a conductive material. In an embodiment, one or more of the contacts, interconnects or vias are composed of a metal species. The metal species may be a pure metal, such as tungsten, nickel, or cobalt, or may be an alloy such as a metal-metal alloy or a metal-semiconductor alloy (e.g., such as a silicide material). In a particular embodiment, one or more of overlying gate contact via 716, or overlying metal interconnect 760 includes a barrier layer and a conductive fill material. In one such embodiment, the barrier layer is a high purity metallic layer, such as described above. In an embodiment, the high purity metallic barrier layer has a total atomic composition including 98% or greater of titanium. In an embodiment, the total atomic composition of the high purity metallic barrier layer further includes 0.5-2% of chlorine. In an embodiment, the high purity metallic barrier layer has a thickness variation of 30% or less. In an embodiment, the conductive fill material is composed of a conductive material such as, but not limited to, Cu, Al, Ti, Zr, Hf, V, Ru, Co, Ni, Pd, Pt, W, Ag, Au or alloys thereof.

In an embodiment (although not shown), providing structure 700 involves formation of a contact pattern which is essentially perfectly aligned to an existing gate pattern while eliminating the use of a lithographic step with exceedingly tight registration budget. In one such embodiment, this approach enables the use of intrinsically highly selective wet etching (e.g., versus conventionally implemented dry or plasma etching) to generate contact openings. In an embodiment, a contact pattern is formed by utilizing an existing gate pattern in combination with a contact plug lithography operation. In one such embodiment, the approach enables elimination of the need for an otherwise critical lithography operation to generate a contact pattern, as used in conventional approaches. In an embodiment, a trench contact grid is not separately patterned, but is rather formed between poly (gate) lines. For example, in one such embodiment, a trench contact grid is formed subsequent to gate grating patterning but prior to gate grating cuts.

Furthermore, the gate stack structure 708 may be fabricated by a replacement gate process. In such a scheme, dummy gate material such as polysilicon or silicon nitride pillar material, may be removed and replaced with permanent gate electrode material. In one such embodiment, a permanent gate dielectric layer is also formed in this process, as opposed to being carried through from earlier processing. In an embodiment, dummy gates are removed by a dry etch or wet etch process. In one embodiment, dummy gates are composed of polycrystalline silicon or amorphous silicon and are removed with a dry etch process including use of SF₆. In another embodiment, dummy gates are composed of polycrystalline silicon or amorphous silicon and are removed with a wet etch process including use of aqueous NH₄OH or tetramethylammonium hydroxide. In one embodiment, dummy gates are composed of silicon nitride and are removed with a wet etch including aqueous phosphoric acid.

In an embodiment, one or more approaches described herein contemplate essentially a dummy and replacement gate process in combination with a dummy and replacement contact process to arrive at structure 700. In one such embodiment, the replacement contact process is performed after the replacement gate process to allow high temperature anneal of at least a portion of the permanent gate stack. For example, in a specific such embodiment, an anneal of at least a portion of the permanent gate structures, e.g., after a gate dielectric layer is formed, is performed at a temperature greater than approximately 600 degrees Celsius. The anneal is performed prior to formation of the permanent contacts.

Referring again to FIG. 7A, the arrangement of semiconductor structure or device 700 places the gate contact over isolation regions. Such an arrangement may be viewed as inefficient use of layout space in certain applications. In another embodiment, however, a semiconductor device has contact structures that contact portions of a gate electrode formed over an active region. In general, prior to (e.g., in addition to) forming a gate contact structure (such as a via) over an active portion of a gate and in a same layer as a trench contact via, one or more embodiments of the present disclosure include first using a gate aligned trench contact process. Such a process may be implemented to form trench contact structures for semiconductor structure fabrication, e.g., for integrated circuit fabrication. In an embodiment, a trench contact pattern is formed as aligned to an existing gate pattern. By contrast, conventional approaches typically involve an additional lithography process with tight registration of a lithographic contact pattern to an existing gate pattern in combination with selective contact etches. For example, a conventional process may include patterning of a poly (gate) grid with separate patterning of contact features.

In a particular embodiment, each of the trench contacts includes a barrier layer and a conductive fill material. In one such embodiment, the barrier layer is a high purity metallic layer, such as described above. In an embodiment, the high purity metallic barrier layer has a total atomic composition including 98% or greater of titanium. In an embodiment, the total atomic composition of the high purity metallic barrier layer further includes 0.5-2% of chlorine. In an embodiment, the high purity metallic barrier layer has a thickness variation of 30% or less. In an embodiment, the conductive fill material is composed of a conductive material such as, but not limited to, Cu, Al, Ti, Zr, Hf, V, Ru, Co, Ni, Pd, Pt, W, Ag, Au or alloys thereof.

It is to be appreciated that not all aspects of the processes described above need be practiced to fall within the spirit and scope of embodiments of the present disclosure. For example, in one embodiment, dummy gates need not ever be formed prior to fabricating gate contacts over active portions of the gate stacks. The gate stacks described above may actually be permanent gate stacks as initially formed. Also, the processes described herein may be used to fabricate one or a plurality of semiconductor devices. The semiconductor devices may be transistors or like devices. For example, in an embodiment, the semiconductor devices are a metal-oxide semiconductor (MOS) transistors for logic or memory, or are bipolar transistors. Also, in an embodiment, the semiconductor devices have a three-dimensional architecture, such as a trigate device, an independently accessed double gate device, or a FIN-FET. One or more embodiments may be particularly useful for fabricating semiconductor devices at a 10 nanometer (10 nm) or smaller technology node.

In an embodiment, as is also used throughout the present description, lithographic operations are performed using 193 nm immersion lithography (i193), extreme ultra-violet (EUV) and/or electron beam direct write (EBDW) lithography, or the like. A positive tone or a negative tone resist may be used. In one embodiment, a lithographic mask is a tri-layer mask composed of a topographic masking portion, an anti-reflective coating (ARC) layer, and a photoresist layer. In a particular such embodiment, the topographic masking portion is a carbon hardmask (CHM) layer and the anti-reflective coating layer is a silicon ARC layer.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

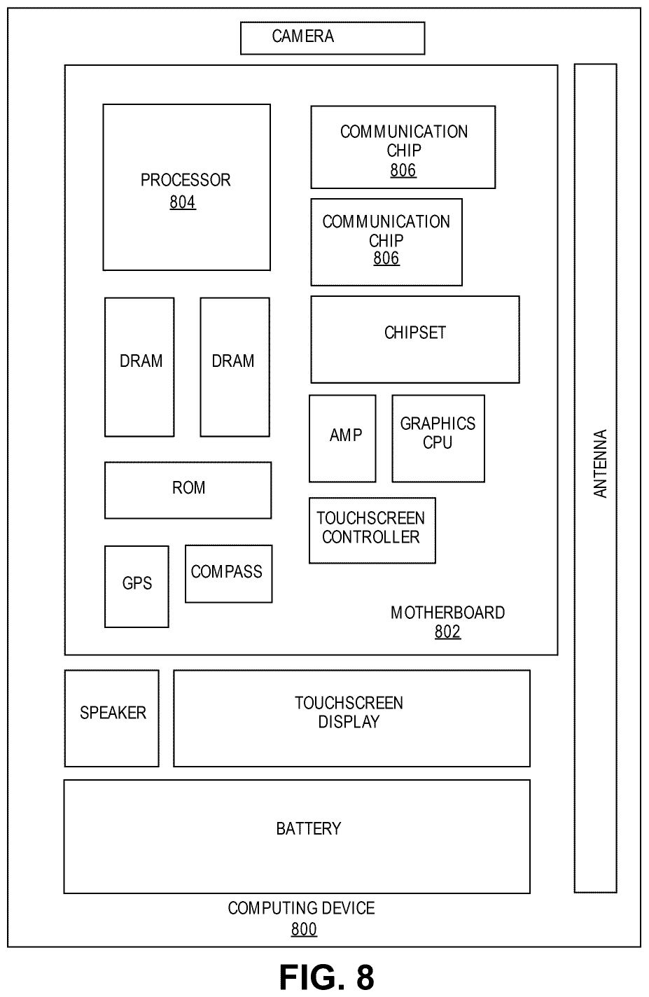

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor includes one or more structures fabricated to include conformal metal contacts, in accordance with implementations of embodiments of the disclosure. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of embodiments of the disclosure, the integrated circuit die of the communication chip includes one or more structures fabricated to include conformal metal contacts, in accordance with implementations of embodiments of the disclosure.

In further implementations, another component housed within the computing device 800 may contain an integrated circuit die that includes one or more structures fabricated to include conformal metal contacts, in accordance with implementations of embodiments of the disclosure.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

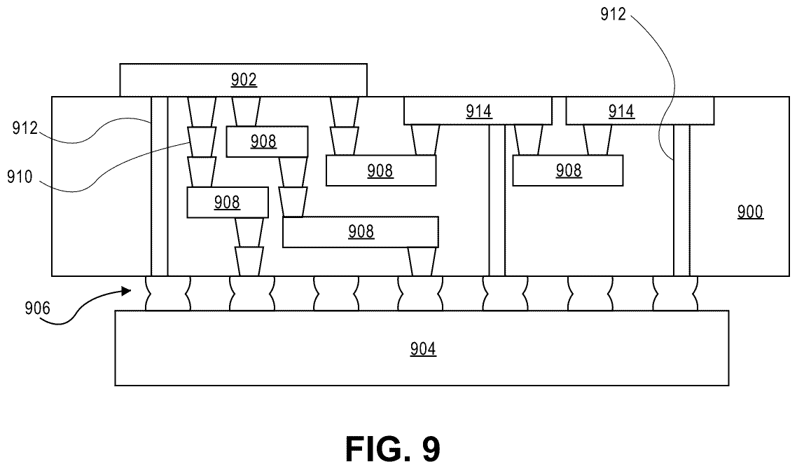

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900.

Thus, embodiments described herein include conformal approaches for fabricating contacts, and semiconductor structures having conformal metal contacts.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description. The terms used in the following claims should not be construed to limit the disclosure to the specific implementations disclosed in the specification and the claims.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment. The following examples pertain to further embodiments. The various features of the different embodiments may be variously combined with some features included and others excluded to suit a variety of different applications.

Example embodiment 1: An integrated circuit structure includes a nanowire coupled to or including a source or drain structure. A dielectric layer is above the source or drain structure. An opening is in the dielectric layer and extends into the source or drain structure, the opening having a bottom and sidewalls. A conductive liner is along the bottom and the sidewalls of the opening. The conductive liner has a thickness variation of less than 10% throughout the conductive liner with respect to the bottom and the sidewalls of the opening, respectively. A conductive fill is on the conductive liner and in a remainder of the opening. A ratio of an area of the conductive fill to the conductive liner in a cross-sectional perspective is at most 3:1.

Example embodiment 2: The integrated circuit structure of example embodiment 1, further including a layer including silicon and titanium, the layer intervening between the source or drain structure and the conductive liner.

Example embodiment 3: The integrated circuit structure of example embodiment 1 or 2, wherein the conductive liner includes a metal or metal alloy selected from the group consisting of Ti, W, Ru, Mo, Cu, Co, CuMn, NiAl, Ta, TiN, and TaN.

Example embodiment 4: The integrated circuit structure of example embodiment 1, 2 or 3, wherein the conductive fill includes a metal or metal alloy selected from the group consisting of W, Ru, Mo, Cu, Co, and NiAl.

Example embodiment 5: The integrated circuit structure of example embodiment 1, 2, 3 or 4, wherein the nanowire includes silicon, and the source or drain structure includes silicon and germanium.

Example embodiment 6: An integrated circuit structure includes a fin coupled to or including a source or drain structure. A dielectric layer is above the source or drain structure. An opening is in the dielectric layer and extends into the source or drain structure, the opening having a bottom and sidewalls. A conductive liner is along the bottom and the sidewalls of the opening. The conductive liner has a thickness variation of less than 10% throughout the conductive liner with respect to the bottom and the sidewalls of the opening, respectively. A conductive fill is on the conductive liner and in a remainder of the opening. A ratio of an area of the conductive fill to the conductive liner in a cross-sectional perspective is at most 3:1.

Example embodiment 7: The integrated circuit structure of example embodiment 6, further including a layer including silicon and titanium, the layer intervening between the source or drain structure and the conductive liner.

Example embodiment 8: The integrated circuit structure of example embodiment 6 or 7, wherein the conductive liner includes a metal or metal alloy selected from the group consisting of Ti, W, Ru, Mo, Cu, Co, CuMn, NiAl, Ta, TiN, and TaN.

Example embodiment 9: The integrated circuit structure of example embodiment 6, 7 or 8, wherein the conductive fill includes a metal or metal alloy selected from the group consisting of W, Ru, Mo, Cu, Co, and NiAl.

Example embodiment 10: The integrated circuit structure of example embodiment 6, 7, 8 or 9, wherein the fin includes silicon, and the source or drain structure includes silicon and germanium.

Example embodiment 11: A computing device includes a board, and a component coupled to the board. The component includes an integrated circuit structure including a nanowire or fin coupled to or including a source or drain structure. A dielectric layer is above the source or drain structure. An opening is in the dielectric layer and extends into the source or drain structure, the opening having a bottom and sidewalls. A conductive liner is along the bottom and the sidewalls of the opening. The conductive liner has a uniform thickness throughout the conductive liner with respect to the bottom and the sidewalls of the opening, respectively. A conductive fill is on the conductive liner and in a remainder of the opening. A ratio of an area of the conductive fill to the conductive liner in a cross-sectional perspective is at most 3:1.

Example embodiment 12: The computing device of example embodiment 11, including the nanowire.

Example embodiment 13: The computing device of example embodiment 11, including the fin.

Example embodiment 14: The computing device of example embodiment 11, 12 or 13, further including a memory coupled to the board.

Example embodiment 15: The computing device of example embodiment 11, 12, 13 or 14, further including a communication chip coupled to the board.

Example embodiment 16: The computing device of example embodiment 11, 12, 13, 14 or 15, further including a battery coupled to the board.

Example embodiment 17: The computing device of example embodiment 11, 12, 13, 14, 15 or 16, further including a camera coupled to the board.

Example embodiment 18: The computing device of example embodiment 11, 12, 13, 14, 15, 16 or 17, further including a display coupled to the board.

Example embodiment 19: The computing device of example embodiment 11, 12, 13, 14, 15, 16, 17 or 18, wherein the component is a packaged integrated circuit die.

Example embodiment 20: The computing device of example embodiment 11, 12, 13, 14, 15, 16, 17, 18 or 19, wherein the component is selected from the group consisting of a processor, a communications chip, and a digital signal processor.

What is claimed is:

1. An integrated circuit structure, comprising:
a nanowire coupled to or including a source or drain structure;
a dielectric layer above the source or drain structure;
an opening in the dielectric layer and extending into the source or drain structure, the opening having a bottom and sidewalls;
a conductive liner along the bottom and the sidewalls of the opening, wherein the conductive liner has a thickness variation of less than 10% throughout the conductive liner with respect to the bottom and the sidewalls of the opening, respectively;
a conductive fill on the conductive liner and in a remainder of the opening, wherein a ratio of an area of the conductive fill to the conductive liner in a cross-sectional perspective is at most 3:1.

2. The integrated circuit structure of claim 1, further comprising:
a layer comprising silicon and titanium, the layer intervening between the source or drain structure and the conductive liner.

3. The integrated circuit structure of claim 1, wherein the conductive liner comprises a metal or metal alloy selected from the group consisting of Ti, W, Ru, Mo, Cu, Co, CuMn, NiAl, Ta, TiN, and TaN.

4. The integrated circuit structure of claim 1, wherein the conductive fill comprises a metal or metal alloy selected from the group consisting of W, Ru, Mo, Cu, Co, and NiAl.

5. The integrated circuit structure of claim 1, wherein the nanowire comprises silicon, and the source or drain structure comprises silicon and germanium.

6. An integrated circuit structure, comprising:
a nanowire coupled to or including a source or drain structure;
a dielectric layer above the source or drain structure;
an opening in the dielectric layer and extending into the source or drain structure, the opening having a bottom and sidewalls;
a conductive liner along the bottom and the sidewalls of the opening, wherein the conductive liner has a thickness variation of less than 10% throughout the conductive liner with respect to the bottom and the sidewalls of the opening, respectively;
a conductive fill on the conductive liner and in a remainder of the opening, wherein a ratio of an area of the conductive fill to the conductive liner in a cross-sectional perspective is at most 3:1.

7. The integrated circuit structure of claim 6, further comprising:
a layer comprising silicon and titanium, the layer intervening between the source or drain structure and the conductive liner.

8. The integrated circuit structure of claim 6, wherein the conductive liner comprises a metal or metal alloy selected from the group consisting of Ti, W, Ru, Mo, Cu, Co, CuMn, NiAl, Ta, TiN, and TaN.

9. The integrated circuit structure of claim 6, wherein the conductive fill comprises a metal or metal alloy selected from the group consisting of W, Ru, Mo, Cu, Co, and NiAl.

10. The integrated circuit structure of claim 6, wherein the fin comprises silicon, and the source or drain structure comprises silicon and germanium.

11. A computing device, comprising:
a board; and
a component coupled to the board, the component including an integrated circuit structure, comprising:
a nanowire or fin coupled to or including a source or drain structure;
a dielectric layer above the source or drain structure;
an opening in the dielectric layer and extending into the source or drain structure, the opening having a bottom and sidewalls;
a conductive liner along the bottom and the sidewalls of the opening, wherein the conductive liner has a uniform thickness throughout the conductive liner with respect to the bottom and the sidewalls of the opening, respectively;
a conductive fill on the conductive liner and in a remainder of the opening, wherein a ratio of an area of the conductive fill to the conductive liner in a cross-sectional perspective is at most 3:1.

12. The computing device of claim 11, comprising the nanowire.

13. The computing device of claim 11, comprising the fin.

14. The computing device of claim 11, further comprising:
a memory coupled to the board.

15. The computing device of claim 11, further comprising:
a communication chip coupled to the board.

16. The computing device of claim 11, further comprising:
a battery coupled to the board.

17. The computing device of claim 11, further comprising:
a camera coupled to the board.

18. The computing device of claim 11, further comprising:
a display coupled to the board.

19. The computing device of claim 11, wherein the component is a packaged integrated circuit die.

20. The computing device of claim 11, wherein the component is selected from the group consisting of a processor, a communications chip, and a digital signal processor.
